(19) United States
(12) Patent Application Publication
(10) Pub. No.: US 2026/0123102 A1
(43) Pub. Date: Apr. 30, 2026

(54) LIGHT-EMITTING ELEMENT AND DISPLAY DEVICE HAVING THE SAME

(71) Applicant: SAMSUNG ELECTRONICS CO., LTD., Suwon-si (KR)

(72) Inventors: Youngtek OH, Suwon-si (KR); Joosung KIM, Suwon-si (KR); Junghun PARK, Suwon-si (KR); Dongchul SHIN, Suwon-si (KR); Kyungwook HWANG, Suwon-si (KR)

(73) Assignee: SAMSUNG ELECTRONICS CO., LTD., Suwon-si (KR)

(21) Appl. No.: 19/095,992

(22) Filed: Mar. 31, 2025

(30) Foreign Application Priority Data
Oct. 29, 2024 (KR) 10-2024-0149926

(51) Int. Cl. H10H 20/812; H10H 20/813; H10H 20/821; H10H 20/825; H10H 29/49

(52) U.S. Cl. CPC H10H 20/812; H10H 20/8131; H10H 20/821; H10H 20/825; H10H 29/49

(57) ABSTRACT

A light-emitting element includes first, second, and third light-emitting structures sequentially stacked on a substrate and configured to emit blue light, green light, and red light, respectively. Each of the first, second, and third light-emitting structures may include a first conductive semiconductor layer, an active layer having a multi-quantum well structure, in which a quantum well layer and a barrier layer are alternately stacked multiple times, and a second conductive semiconductor layer, which are sequentially stacked. An absorption conversion rate of the third light-emitting structure of the blue light may be 3% or less.

### CROSS-REFERENCE TO RELATED APPLICATION

This application claims the benefit of Korean Patent Application No. 10-2024-0149926, filed on Oct. 29, 2024, in the Korean Intellectual Property Office, the disclosure of which is incorporated herein in its entirety by reference.

### BACKGROUND

### 1. Field

Embodiments of the present disclosure relate to a light-emitting element and a display device having the same.

### 2. Description of Related Art

Light-emitting elements such as, for example, light-emitting diodes (LEDs), have been known as next-generation light sources with advantages, such as long life, low power consumption, a fast response speed, environmental friendliness, etc., compared with light sources according to the related art, and thus, the industrial demand thereof has increased due to such advantages. LEDs have been typically used in various products, such as lighting devices, display devices, etc.

Recently, ultra-small LEDs in units of micrometers or nanometers, which are referred to as micro-LEDs, have been developed. Micro-LEDs are applied to relatively large display devices such as televisions, and further to small display devices such as displays for augmented reality (AR) devices. Micro-LEDs applied to small display devices may have a vertical arrangement structure in which red, green, and blue (RGB) sub-pixels are stacked vertically. In the micro-LEDs having a vertical arrangement structure, light generated from a sub-pixel having high bandgap energy is absorbed by other sub-pixels having low bandgap energy so that unexpected sub-pixels may emit light.

### SUMMARY

According to some embodiments of the present disclosure, a light-emitting element which may reduce color mixing by absorption-induced-luminescence, and a display device having the element, may be provided.

According to some embodiments of the present disclosure, a light-emitting element may be provided and include: a substrate; a first light-emitting structure configured to emit blue light; a second light-emitting structure configured to emit green light; and a third light-emitting structure configured to emit red light, wherein the first light-emitting structure, the second light-emitting structure, and the third light-emitting structure are stacked on the substrate, wherein each of the first light-emitting structure, the second light-emitting structure, and the third light-emitting structure includes: a first conductive semiconductor layer, an active layer including a multi-quantum well structure, wherein the multi-quantum well structure includes quantum well layers and barrier layers that are alternately stacked, and a second conductive semiconductor layer, wherein the first conductive semiconductor layer, the active layer, and the second conductive semiconductor layer are sequentially stacked, and wherein an absorption conversion rate of the third light-emitting structure of the blue light is 3% or less.

According to one or more embodiments of the present disclosure, an absorption conversion rate of the second light-emitting structure of the blue light is 6% or less.

According to one or more embodiments of the present disclosure, a total thickness and a total number of the quantum well layers of the third light-emitting structure are respectively less than or equal to a total thickness and a total number of the quantum well layers of the first light-emitting structure.

According to one or more embodiments of the present disclosure, a total thickness and a total number of the quantum well layers of the second light-emitting structure are respectively less than or equal to a total thickness and a total number of the quantum well layers of the first light-emitting structure.

According to one or more embodiments of the present disclosure, the quantum well layers include InGaN, the barrier layers include GaN, the first conductive semiconductor layer includes n-GaN, and the second conductive semiconductor layer includes p-GaN.

According to one or more embodiments of the present disclosure, an indium concentration of the quantum well layers of the first light-emitting structure is 13% to 18%, an indium concentration of the quantum well layers of the second light-emitting structure is 20% to 25%, and an indium concentration of the quantum well layers of the third light-emitting structure is 30% to 35%.

According to one or more embodiments of the present disclosure, a total thickness of the quantum well layers of each of the first light-emitting structure, the second light-emitting structure, and the third light-emitting structure is 30 nm or less.

According to one or more embodiments of the present disclosure, a total number of the quantum well layers of each of the first light-emitting structure, the second light-emitting structure, and the third light-emitting structure is 10 or less.

According to one or more embodiments of the present disclosure, a peak internal quantum efficiency of the first light-emitting structure is 50% or less, a total thickness of the quantum well layers of the first light-emitting structure is 30 nm or less, and a total number of the quantum well layers of the first light-emitting structure is 10 or less.

According to one or more embodiments of the present disclosure, a peak internal quantum efficiency of the second light-emitting structure is 30% or less, a peak internal quantum efficiency of the third light-emitting structure is 10% or less, a total thickness of the quantum well layers of each of the second light-emitting structure and the third light-emitting structure is 30 nm or less, and a total number of the quantum well layers of each of the second light-emitting structure and the third light-emitting structure is 10 or less.

According to one or more embodiments of the present disclosure, a peak internal quantum efficiency of the second light-emitting structure is 30% or less, a peak internal quantum efficiency of the third light-emitting structure is 20% or less, a total thicknesses of the quantum well layers of the second light-emitting structure is 30 nm or less, a total thicknesses of the quantum well layers of the third light-emitting structure is 15 nm or less, a total number of the quantum well layers of the second light-emitting structure is 10 or less, and a total number of the quantum well layers of the third light-emitting structure is 5 or less.

According to one or more embodiments of the present disclosure, a peak internal quantum efficiency of the second light-emitting structure is 60% or less, a peak internal quantum efficiency of the third light-emitting structure is 10% or less, a total thicknesses of the quantum well layers of the second light-emitting structure is 15 nm or less, a total thicknesses of the quantum well layers of the third light-emitting structure is 30 nm or less, a total number of the quantum well layers of the second light-emitting structure is 5 or less, and a total number of the quantum well layers of the third light-emitting structure is 10 or less.

According to one or more embodiments of the present disclosure, a peak internal quantum efficiency of the second light-emitting structure is 60% or less, a peak internal quantum efficiency of the third light-emitting structure is 20% or less, a total thickness of the quantum well layers of each of the second light-emitting structure and the third light-emitting structure is 15 nm or less, and a total number of the quantum well layers of each of the second light-emitting structure and the third light-emitting structure is 5 or less.

According to one or more embodiments of the present disclosure, the light-emitting element may further include: a first insulating layer between the first light-emitting structure and the second light-emitting structure; and a second insulating layer between the second light-emitting structure and the third light-emitting structure.

According to one or more embodiments of the present disclosure, the first insulating layer and the second insulating layer include AlGaN.

According to one or more embodiments of the present disclosure, the third light-emitting structure is an uppermost light-emitting structure, among the first light-emitting structure, the second light-emitting structure, and the third light-emitting structure, with respect to a light emission direction of the light-emitting element.

According to one or more embodiments of the present disclosure, the first light-emitting structure is an uppermost light-emitting structure, among the first light-emitting structure, the second light-emitting structure, and the third light-emitting structure, with respect to a light emission direction of the light-emitting element.

According to embodiments of the present disclosure, a display device may be provided and include a display panel including: a plurality of light-emitting elements, each of the plurality of light-emitting elements including: a first light-emitting structure configured to emit blue light; a second light-emitting structure configured to emit green light; and a third light-emitting structure configured to emit red light; and a driving circuit configured to switch the plurality of light-emitting elements on or off. The display panel may further include a controller configured to input, based on an image signal, a signal for switching the plurality of light-emitting elements on or off to the driving circuit, wherein the first light-emitting structure, the second light-emitting structure, and the third light-emitting structure are alternatively stacked on the substrate, wherein each of the first light-emitting structure, the second light-emitting structure, and the third light-emitting structure includes: a first conductive semiconductor layer; an active layer including a multi-quantum well structure, wherein the multi-quantum well structure includes quantum well layers and barrier layers that are alternately; and a second conductive semiconductor layer, wherein the first conductive semiconductor layer, the active layer, and the second conductive semiconductor layer are sequentially stacked, and wherein an absorption conversion rate of the first light-emitting structure of the blue light is 3% or less.

According to embodiments of the present disclosure, a light-emitting element may be provided and include: a first light-emitting structure configured to emit first light of a first color; a second light-emitting structure configured to emit second light of a second color; and a third light-emitting structure configured to emit third light of a third color, wherein the first color, the second color, and the third color are different from each other, wherein the first light-emitting structure, the second light-emitting structure, and the third light-emitting structure are stacked on the substrate, wherein each of the first light-emitting structure, the second light-emitting structure, and the third light-emitting structure includes: a first conductive semiconductor layer, an active layer including a multi-quantum well structure, wherein the multi-quantum well structure includes quantum well layers and barrier layers that are alternately stacked, and a second conductive semiconductor layer, wherein the first conductive semiconductor layer, the active layer, and the second conductive semiconductor layer are sequentially stacked, and wherein an absorption conversion rate of the third light-emitting structure of the first light is 3% or less.

According to one or more embodiments of the present disclosure, an absorption conversion rate of the second light-emitting structure of the first light is 6% or less. Additional aspects of embodiments of the present disclosure will be set forth in part in the description which follows and, in part, will be apparent from the description, or may be learned by practice of the presented example embodiments.

### BRIEF DESCRIPTION OF DRAWINGS

These and/or other aspects will become apparent and more readily appreciated from the following description of the embodiments, taken in conjunction with the accompanying drawings in which:

FIG. 1 is a schematic cross-sectional view of a light-emitting element according to an embodiment;

FIG. 2 is a chart showing a variety of combinations of a total number and thickness of quantum well layers including InGaN and a peak internal quantum efficiency (peak IQE) of a second light-emitting structure so that a absorption conversion rate of the second light-emitting structure of blue light is within 6%;

FIG. 3 is a graph showing a result of simulating an absorption conversion rate according to the number of quantum well layers including InGaN when the peak IQE of the second light-emitting structure is 30%;

FIG. 4 is a chart showing a variety of combinations of a total number and thickness of quantum well layers including InGaN and a peak IQE of a third light-emitting structure so that a absorption conversion rate of the third light-emitting structure of blue light is within 6%;

FIG. 5 is a graph showing a result of simulating an absorption conversion rate according to the number of quantum well layers including InGaN when the peak IQE of the third light-emitting structure is 10%;

FIG. 6 is a graph showing an absorption spectrum of light emitted from the light-emitting element illustrated in FIG. 1 when the light-emitting element generates blue light;

FIG. 7 is a schematic cross-sectional view of a light-emitting element according to an embodiment;

FIG. 8 is a schematic cross-sectional view of a light-emitting element according to an embodiment;

FIG. 9 is a schematic cross-sectional view of a light-emitting element according to an embodiment;

FIG. 10 is a schematic view showing an example of a display device;

FIG. 11 is a block diagram showing an example of an electronic device including a display;

FIG. 12 illustrates an example of a mobile device as an application example of the electronic device of FIG. 11;

FIG. 13 illustrates an example of a head-up display device for vehicles as an application example of the electronic device of FIG. 11;

FIG. 14 illustrates an example of augmented reality glasses or virtual reality glasses as an application example of the electronic device of FIG. 11;

FIG. 15 illustrates an example of a large signage as an application example of the electronic device of FIG. 11; and

FIG. 16 illustrates an example of a wearable display as an application example of the electronic device of FIG. 11.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain non-limiting example aspects. As used herein, the term “and/or” includes any and all combinations of one or more of the associated listed items.

Technology for applying light-emitting elements, such as micro light-emitting diodes (LEDs), to displays has advanced significantly, and televisions using micro-LEDs have begun to be provided. Furthermore, micro-LEDs may be applied to augmented reality devices. In displays for augmented reality devices, very small micro-LED display chips (or panels) may be made monolithically at the wafer level without a process of transferring micro-LEDs like in television displays. In television displays, the size of one pixel may be tens to hundreds of micrometers, but in small or ultra-small displays such as, for example, augmented reality devices, the size of one pixel may be very small, about only a few micrometers.

In order to display a color image on a display, one pixel (color pixel) may include RGB sub-pixels. The arrangement structure of RGB sub-pixels may include a horizontal arrangement structure and a vertical arrangement structure. In the horizontal arrangement structure, RGB sub-pixels are arranged horizontally, and in the vertical arrangement structure, RGB sub-pixels are arranged vertically. In the horizontal arrangement structure, each of sub-pixels may be referred to as a micro-LED. In the vertical arrangement structure, a micro-LED may be a monolithic RGB micro-LED in which RGB sub-pixels are incorporated.

For a color pixel of a given size, the horizontal arrangement structure may require sub-pixels to be manufactured in a smaller size than a size in the vertical arrangement structure, making the horizontal process more difficult. In the vertical arrangement structure, as sub-pixels are arranged vertically, vertical process difficulty is high. However, in the vertical arrangement structure, compared with the horizontal arrangement structure, sub-pixels may be manufactured in a larger size, which results in greater efficiency, that is, external quantum efficiency (EQE), compared to the horizontal arrangement structure.

Color mixing may be a problem in micro-LEDs that have vertical arrangement structures. For example, when blue light is emitted, the blue light generated from the high bandgap of a blue sub-pixel may be absorbed by red/green sub-pixels with a lower bandgap, resulting in absorption-induced-luminescence, that is, red/green light are emitted. According to embodiments of the present disclosure, a light-emitting element and a display device employing the same may be provided, wherein the light-emitting element may reduce absorption-induced-luminescence by controlling a number and thickness of layers in a multi-quantum well structure in an active layer of sub-pixels having relatively low bandgap according to an internal quantum efficiency of the sub-pixels having a relatively low bandgap.

Hereinafter, non-limiting example embodiments of the present disclosure of a light-emitting element and a display device employing the same are described in detail with reference to the accompanying drawings. Throughout the drawings, like reference numerals denote like elements, and sizes of components in the drawings may be exaggerated for convenience of explanation, and clarity. Furthermore, as embodiments described below are examples, other modifications may be produced from the embodiments, and such other modifications are included within the spirit and scope of the present disclosure.

When a constituent element is disposed “above” or “on” another constituent element, the constituent element may include not only an element directly contacting and disposed on the other constituent element, but also an element disposed above the other constituent element in a non-contact manner. As used herein, the singular forms “a,” “an” and “the” are intended to include the plural forms as well, unless the context clearly indicates otherwise. It will be further understood that the terms “comprises” (or “includes”) and/or “comprising” (or “including”) used herein specify the presence of stated features or elements, but do not preclude the presence or addition of one or more other features or elements.

The use of the terms “a,” “an,” “the,” and similar referents in the context of describing the present disclosure is to be construed to cover both the singular and the plural. Also, the operations of all methods described herein can be performed in any suitable order unless otherwise indicated herein or otherwise clearly contradicted by context. The present disclosure is not limited to the described order of the steps.

Furthermore, the connecting lines, or connectors shown in the various figures presented are intended to represent functional relationships and/or physical or logical couplings between the various elements. It should be noted that many alternative or additional functional relationships, physical connections, or logical connections may be present in a practical device.

The use of any and all examples, or language (e.g., “such as”) provided herein, is intended merely to better illuminate example embodiments of the present disclosure and does not pose a limitation on the scope of the present disclosure unless otherwise stated.

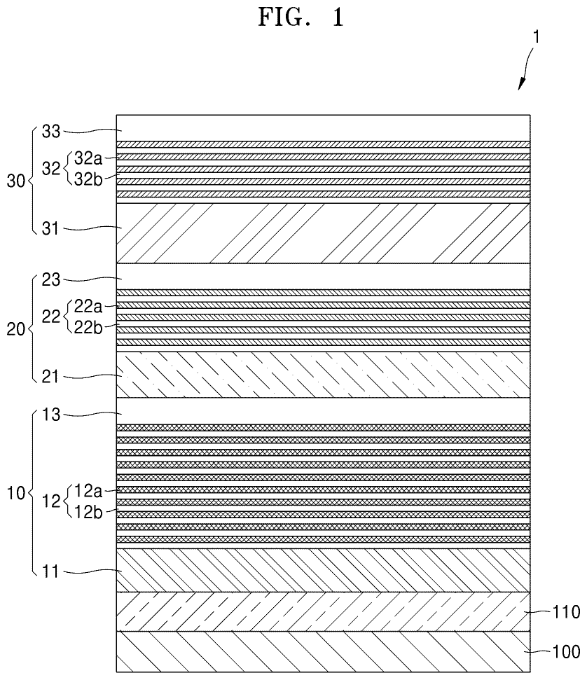

FIG. 1 is a schematic cross-sectional view of a light-emitting element 1 according to an embodiment. The light-emitting element 1 of the present embodiment may be a vertical stack-type light-emitting element in which a plurality of sub-pixels are vertically stacked. The light-emitting element 1 may be, for example, a monolithic color micro-LED.

Referring to FIG. 1, the light-emitting element 1 may include a plurality of light-emitting structures that are vertically stacked. The light-emitting element 1 may correspond to one pixel in a display device, and the light-emitting structures may correspond to sub-pixels that are vertically stacked and form one pixel. The light-emitting structures may each include a first conductive semiconductor layer, an active layer, and a second conductive semiconductor layer, which may be sequentially stacked.

The light-emitting structures may be formed of Group III-V nitride semiconductor materials. Group III-V nitride semiconductor materials may include, for example, GaN, InGaN, AlInGaN, AlGaInP, or the like. For example, the light-emitting structures may be formed of GaN-based semiconductor materials. Each of the light-emitting structures may have a structure in which a first conductive semiconductor layer, an active layer having a quantum well structure, and a second conductive semiconductor layer are sequentially stacked. The emission wavelength band may be determined as the band gap energy is controlled depending on the composition ratio of indium (In) in the material layer containing indium (In) in the active layer.

The light-emitting structures may emit light of different wavelengths. In the present embodiment, the light-emitting structures may each include a first light-emitting structure 10, a second light-emitting structure 20, and a third light-emitting structure 30, which may be sequentially stacked. In the present embodiment, the first light-emitting structure 10 may form a lower layer, while the second light-emitting structure 20 may be stacked on the first light-emitting structure 10, and the third light-emitting structure 30 may be stacked on the second light-emitting structure 20. The third light-emitting structure 30 may be located as a top layer (e.g., an uppermost light-emitting structure) among the light-emitting structures with respect to a light emission direction.

For example, the first light-emitting structure 10, the second light-emitting structure 20, and the third light-emitting structure 30 may be formed on and above a substrate 100. The substrate 100, as a growth substrate for semiconductor single crystal growth, may use, for example, a silicon (Si) substrate, a silicon carbide (SiC) substrate, a sapphire substrate, or the like. In addition, various substrates including materials appropriate for growth of a light-emitting structure to form, for example, AlN, AlGaN, ZnO, GaAs, MgAl₂O₄, MgO, LiAlO₂, LiGaO₂, GaN, or the like, may be used. As necessary, a buffer layer 110 needed for epitaxial growth of a light-emitting structure may be provided on a surface of the substrate 100, and the light-emitting structure may grow on the buffer layer 110.

The first light-emitting structure 10 may include a first conductive semiconductor layer 11, an active layer 12 having a quantum well structure, and a second conductive semiconductor layer 13, which may be sequentially stacked. The first conductive semiconductor layer 11 may be a semiconductor layer doped with first type impurities such as, for example, a GaN layer. The active layer 12 may be a layer that emits light by electron-hole recombination. The active layer 12 may be formed by growing on the first conductive semiconductor layer 11. The active layer 12 may have a quantum well structure. For example, the active layer 12 may have a multi-quantum well structure obtained by periodically changing x, y, and z values in AlₓGa_{y}In_{z}N to adjust a band gap. For example, a quantum well layer 12a and a barrier layer 12b forming a pair in the form of InGaN/GaN, InGaN/InGaN, InGaN/AlGaN, or InGaN/InAlGaN may form a quantum well structure of the first light-emitting structure 10, and the pair of the quantum well layer 12a and the barrier layer 12b may be stacked multiple times. The emission wavelength band may be adjusted as the band gap energy is controlled depending on the composition ratio of In in the material layer containing In in the active layer 12. The second conductive semiconductor layer 13 may be formed on the active layer 12. The second conductive semiconductor layer 13 may be a semiconductor layer doped with second type impurities such as, for example, a GaN layer. For example, the first type impurities may be n-type impurities, and the second type impurities may be p-type impurities. Reversely, the first type impurities may be p-type impurities, and the second type impurities may be n-type impurities. Si, Ge, Se, Te, etc., may be used as the n-type impurities. Mg, Zn, Be, etc. may be used as the p-type impurities. In the present embodiment, the first type impurities may be n-type impurities, and the second type impurities may be p-type impurities. In this case, the first conductive semiconductor layer 11 may be an n-GaN layer, and the second conductive semiconductor layer 13 may be a p-GaN layer. The active layer 12 may be a multi-quantum well structure. The quantum well layer 12a may include InGaN, and the barrier layer 12b may include GaN.

The second light-emitting structure 20 may include a first conductive semiconductor layer 21, an active layer 22 having a multi-quantum well structure, and a second conductive semiconductor layer 23, which may be sequentially stacked. The descriptions of the first conductive semiconductor layer 11, the active layer 12, and the second conductive semiconductor layer 13 of the first light-emitting structure 10 may be applied to the first conductive semiconductor layer 21, the active layer 22, and the second conductive semiconductor layer 23 of the second light-emitting structure 20. In the present embodiment, the first type impurities may be n-type impurities, and the second type impurities may be p-type impurities. In this case, the first conductive semiconductor layer 21 may be an n-GaN layer, and the second conductive semiconductor layer 23 may be a p-GaN layer. The active layer 22 may be a multi-quantum well structure. A quantum well layer 22a of the active layer 22 may include InGaN, and a barrier layer 22b of the active layer 22 may include GaN.

The third light-emitting structure 30 may include a first conductive semiconductor layer 31, an active layer 32 having a multi-quantum well structure, and a second conductive semiconductor layer 33, which may be sequentially stacked. The descriptions of the first conductive semiconductor layer 11, the active layer 12, and the second conductive semiconductor layer 13 of the first light-emitting structure 10 may be applied to the first conductive semiconductor layer 31, the active layer 32, and the second conductive semiconductor layer 33 of the third light-emitting structure 30. In the present embodiment, the first type impurities may be n-type impurities, and the second type impurities may be p-type impurities. In this case, the first conductive semiconductor layer 31 may be an n-GaN layer, and the second conductive semiconductor layer 33 may be a p-GaN layer. The active layer 32 may be a multi-quantum well structure. A quantum well layer 32a of the active layer 32 may include InGaN, and a barrier layer 32b of the active layer 32 may include GaN.

As an example, the third light-emitting structure 30, which may be located at the exit light side of the light-emitting element 1 and may for the top layer (e.g., the uppermost light-emitting structure) of the light-emitting structures, may emit red light, for example, light with a wavelength range of 630±20 nm. The first light-emitting structure 10 and the second light-emitting structure 20 may emit light such as, for example, blue light (e.g., light of a wavelength range of 460±20 nm) and green light (e.g., light of a wavelength range of 530±20 nm), respectively. The first light-emitting structure 10 and the second light-emitting structure 20 may emit light such as, for example, green light and blue light, respectively. As an example, the In concentration of the quantum well layer 12a of the first light-emitting structure 10 may be 13% to 18%, the In concentration of the quantum well layer 22a of the second light-emitting structure 20 may be 20% to 25%, and the In concentration of the quantum well layer 32a of the third light-emitting structure 30 may be 30% to 35%.

As described above, the bandgap energy of the active layer that emits blue light is higher than the bandgap energy of the active layers that emit green light and red light, respectively. As the blue light is absorbed by the active layers that emit green light and red light, such active layers may emit undesired green light and red light, respectively. Furthermore, the bandgap energy of the active layer that emits green light is higher than the bandgap energy of the active layer that emits red light. As the green light is absorbed by the active layer that emits red light, such active layer may emit undesired red light in a comparative embodiment. Such absorption-induced-luminescence may cause color mixing when a light-emitting element of a comparative embodiment is applied to a display device or the like.

In order to reduce absorption-induced-luminescence, the absorption conversion rates of the second light-emitting structure 20 and the second light-emitting structure 30 of blue light may be appropriately restricted. The absorption conversion rate of each of the second light-emitting structure 20 and the third light-emitting structure 30 increases as the luminous efficiency of the first light-emitting structure 10 increases. The luminous efficiency of the first light-emitting structure 10 increases as the photoelectric conversion rate and the peak internal quantum efficiency (peak IQE) of the first light-emitting structure 10 increases. The photoelectric conversion rate of the first light-emitting structure 10 may depend on the number, that is, the total thickness, of the quantum well layer 12a. Accordingly, considering the process difficulty of the light-emitting element 1, the number and the total thickness and the peak IQE of the quantum well layer 12a of the first light-emitting structure 10 may be restricted. In the present embodiment, the number and the total thickness of the quantum well layers 12a of the first light-emitting structure 10 may be 10 or less and 30 nm or less, respectively. Furthermore, the peak IQE of the first light-emitting structure 10 may be 50% or less.

Considering the process difficulty and the productivity of the light-emitting element 1, the number of each of quantum well layers 22a and 32a of the second light-emitting structure 20 and the third light-emitting structure 30 may be 10 or less. In other words, the total thickness of each of the quantum well layers 22a and 32a may be 30 nm or less.

The absorption conversion rate of each of the second light-emitting structure 20 and the third light-emitting structure 30 decreases as the number of quantum well layers 22a and 32a corresponding thereto decreases. In other words, the absorption conversion rate of each of the second light-emitting structure 20 and the third light-emitting structure 30 decreases as the total thickness of each of the quantum well layers 22a and 33a decreases. Considering the above points, the total thickness and number of quantum well layers 22a of the second light-emitting structure 20 may be less than or equal to the total thickness and number of quantum well layers 12a of the first light-emitting structure 10. Likewise, the total thickness and number of quantum well layers 32a of the third light-emitting structure 30 may be less than or equal to the total thickness and number of quantum well layers 12a of the first light-emitting structure 10.

The absorption conversion rates of the second light-emitting structure 20 and the third light-emitting structure 30 of blue light may be determined to satisfy the coverage rate for a color space. For example, the absorption conversion rate of the second light-emitting structure 20 of blue light may be within 6%, and the absorption conversion rate of the third light-emitting structure 30 of blue light may be within 3%. Accordingly, 95% or more of the DCI-P3 color space may be covered.

The absorption conversion rates of the second light-emitting structure 20 and the third light-emitting structure 30 of blue light may be affected by the peak IQE of each of the second light-emitting structure 20 and the third light-emitting structure 30. Accordingly, the total thickness and number of quantum well layers 22a of the second light-emitting structure 20 may be determined such that the absorption conversion rate of blue light is 3% or less, considering the peak internal quantum efficiency of the second light-emitting structure 20. The total thickness and the number of quantum well layers 32a of the third light-emitting structure 30 may be determined such that the absorption conversion rate of blue light is 6% or less, considering the peak internal quantum efficiency of the third light-emitting structure 30.

Described below are various examples of the active layers 22 and 23 to make the absorption conversion rates of the second light-emitting structure 20 and the third light-emitting structure 30 of blue light to be within 6% and within 3%, respectively. An absorption rate A may be calculated by Equation 1 below, where α is an absorption coefficient and t is the total thickness of quantum well layers. An absorption conversion rate R_{C} may be calculated by Equation 2 below, where IQE is the peak IQE of a light-emitting structure.

$$A = 1 - {e}^{- α t} \qquad ( Equation l )$$

$${R}_{C} = IQE * ( 1 - {e}^{- α t} ) \qquad ( Equation 2 )$$

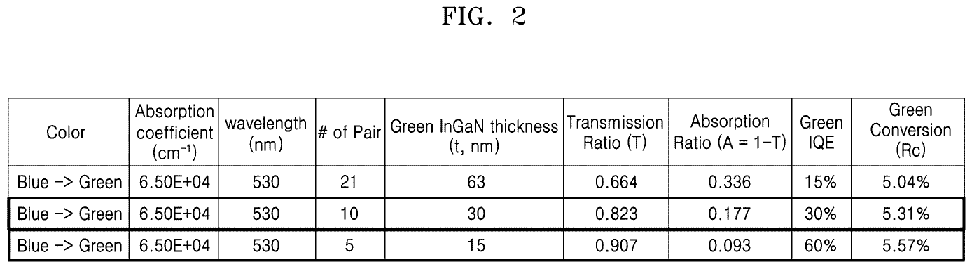

FIG. 2 is a chart showing various combinations of the total number and the total thickness of the quantum well layers 22a including InGaN and the peak IQE of the second light-emitting structure 20 such that the absorption conversion rate of the second light-emitting structure 20 of blue light is within 6%. The absorption coefficient may be 6.5×10⁴ cm⁻¹. The thickness of a single layer of the quantum well layers 22a including InGaN may be 3 nm. Referring to FIG. 2, for example, when the peak IQE of the second light-emitting structure 20 is 30%, the total number of quantum well layers 22a including InGaN may be 10, and the total thickness of the quantum well layers 22a including InGaN may be 30 nm. In this state, the absorption conversion rate of the second light-emitting structure 20 of blue light may be about 5.31%. Furthermore, for example, when the peak IQE of the second light-emitting structure 20 is 60%, the number of quantum well layers 22a including InGaN may be 5, and the total thickness of the quantum well layers 22a including InGaN may be 15 nm. In this state, the absorption conversion rate of the second light-emitting structure 20 of blue light may be about 5.57%.

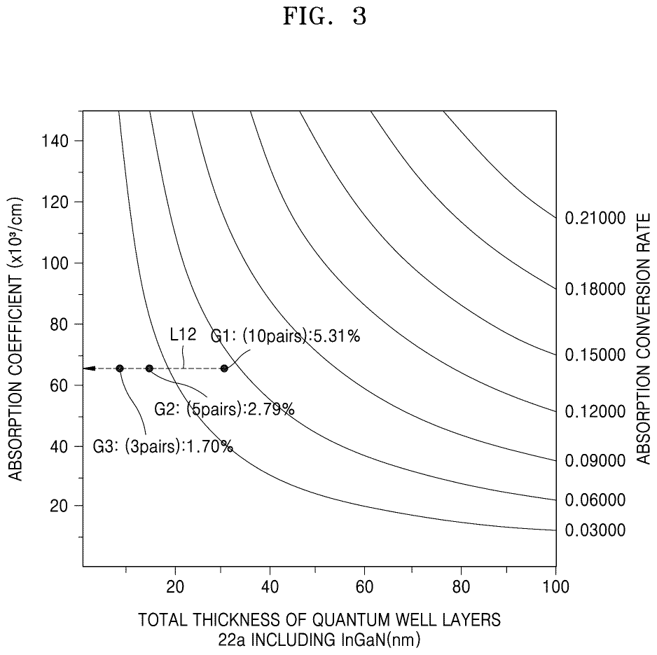

FIG. 3 is a graph showing a result of simulating the absorption conversion rate according to the number of quantum well layers 22a including InGaN when the peak IQE of the second light-emitting structure is 30%. In FIG. 3, curves are contour lines of absorption conversion rates. Referring to FIG. 3, the absorption coefficient of the second light-emitting structure 20 with respect to blue light may be constant as 6.5×10⁴ cm⁻¹. Furthermore, the peak IQE of the second light-emitting structure 20 may also be constant as 30%. When the number of quantum well layers 22a including InGaN is changed, the absorption conversion rate changes along a line L12 that is parallel to the horizontal axis and has a absorption coefficient of 6.5×10⁴ cm⁻¹. The absorption conversion rate increases as the number of quantum well layers 22a including InGaN increases, and decreases as the number of the quantum well layer 22a including InGaN decreases. For example, in FIG. 3, as indicated by G1, when the total number of the quantum well layer 22a including InGaN is 10, that is, the total thickness of the quantum well layers 22a including InGaN is 30 nm, the absorption conversion rate may be 5.31%. In FIG. 3, as indicated by G2, when the total number of the quantum well layer 22a including InGaN is 5, that is, the total thickness of the quantum well layers 22a including InGaN is 15 nm, the absorption conversion rate may be 2.79%. In FIG. 3, as indicated by G3, when the number of the quantum well layer 22a including InGaN is 3, that is, the total thickness of the quantum well layers 22a including InGaN is 9 nm, the absorption conversion rate may be 1.70%. As such, when the peak IQE of the second light-emitting structure 20 is constant as 30%, by decreasing the total number of the quantum well layer 22a including InGaN to be less than 10, that is, the total thickness of the quantum well layers 22a including InGaN to be less than 30 nm, the absorption conversion rate of the second light-emitting structure 20 may be within 6%. Furthermore, the absorption conversion rate of the second light-emitting structure 20 decreases as the peak IQE of the second light-emitting structure 20 decreases. Accordingly, when the peak IQE of the second light-emitting structure 20 is 30% or less, by decreasing the number of the quantum well layer 22a including InGaN to be less than 10, that is, the total thickness of the quantum well layers 22a including InGaN to be less than 30 nm, the absorption conversion rate of the second light-emitting structure 20 may be within 6%.

The descriptions presented with reference to FIG. 3 may be applied to a case when the peak IQE of the second light-emitting structure 20 is 60%. Accordingly, when the peak IQE of the second light-emitting structure 20 is 60% or less, by decreasing the number of the quantum well layer 22a including InGaN to be less than 5, that is, the total thickness of the quantum well layers 22a including InGaN to be less than 15 nm, the absorption conversion rate of the second light-emitting structure 20 may be within 6%.

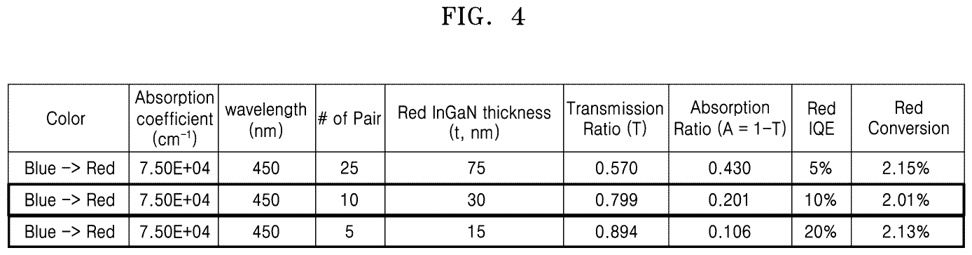

FIG. 4 is a graph showing a variety of combinations of the total number and the total thickness of the quantum well layers 32a including InGaN and the peak IQE of the third light-emitting structure so that the absorption conversion rate of the third light-emitting structure 30 of blue light is within 6%. The absorption coefficient may be 7.5×10⁴ cm⁻¹. The thickness of a single layer of the quantum well layers 32a including InGaN may be 3 nm. Referring to FIG. 4, for example, when the peak IQE of the third light-emitting structure 30 is 10%, the number of quantum well layers 32a including InGaN may be 10, and the total thickness of the quantum well layers 32a including InGaN may be 30 nm. In this state, the absorption conversion rate of the third light-emitting structure 30 of blue light may be about 2.01%. Furthermore, for example, when the peak IQE of the third light-emitting structure 30 is 20%, the number of quantum well layers 32a including InGaN may be 5, and the total thickness of the quantum well layers 32a including InGaN may be 15 nm. In this state, the absorption conversion rate of the third light-emitting structure 30 of blue light may be about 2.13%.

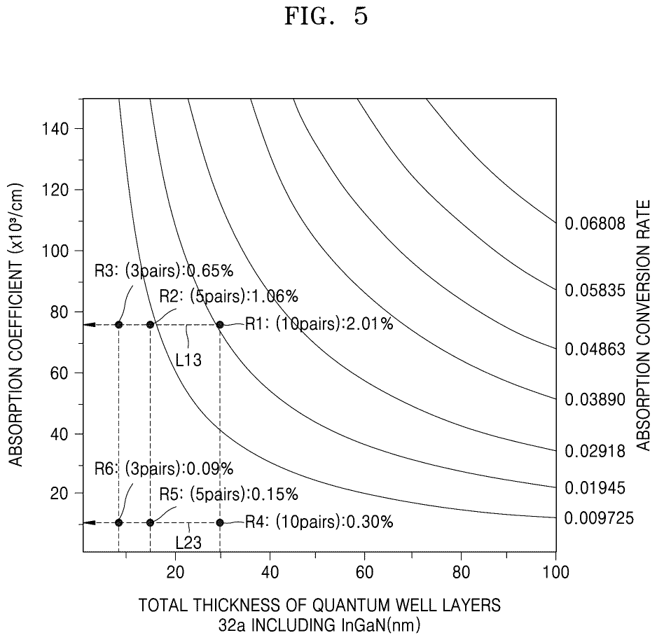

FIG. 5 is a graph showing a result of simulating an absorption conversion rate according to the number of quantum well layers 32a including InGaN when the peak IQE of the third light-emitting structure 30 is 10%. In FIG. 5, curves are contour lines of absorption conversion rates. Referring to FIG. 5, the absorption coefficient of the third light-emitting structure 30 with respect to blue light may be constant as 7.5×10⁴ cm⁻¹. Furthermore, the peak IQE of the third light-emitting structure 30 may also be constant as 10%. When the number of quantum well layers 32a including InGaN is changed, the absorption conversion rate changes along a line L13 that is parallel to the horizontal axis and has a absorption coefficient of 7.5×10⁴ cm⁻¹. The absorption conversion rate increases as the number of quantum well layers 32a including InGaN increases, and decreases as the number of quantum well layers 32a including InGaN decreases. For example, in FIG. 5, as indicated by R1, when the total number of quantum well layers 32a including InGaN is 10, that is, the total thickness of the quantum well layers 32a including InGaN is 30 nm, the absorption conversion rate is 2.01%. In FIG. 5, as indicated by R2, when the total number of quantum well layers 32a including InGaN is 5, that is, the total thickness of the quantum well layers 32a including InGaN is 15 nm, the absorption conversion rate may be 1.06%. In FIG. 5, as indicated by R3, when the number of quantum well layers 32a including InGaN is 3, that is, the total thickness of the quantum well layers 32a including InGaN is 9 nm, the absorption conversion rate may be 0.65%. As such, when the peak IQE of the third light-emitting structure 30 is constant as 10%, by decreasing the number of quantum well layers 32a including InGaN to be less than 10, that is, the total thickness of the quantum well layers 32a including InGaN to be less than 30 nm, the absorption conversion rate of the third light-emitting structure 30 may be within 3%. Furthermore, the absorption conversion rate of the third light-emitting structure 30 decreases as the peak IQE of the third light-emitting structure 30 decreases. Accordingly, when the peak IQE of the third light-emitting structure 30 is 10% or less, by decreasing the number of quantum well layers 32a including InGaN to be less than 10, that is, the total thickness of the quantum well layers 32a including InGaN to be less than 30 nm, the absorption conversion rate of the third light-emitting structure 30 may be within 3%.

The descriptions provided with reference to FIG. 5 may be applied to a case when the peak IQE of the third light-emitting structure 30 is 20%. Accordingly, when the peak IQE of the third light-emitting structure 30 is 20% or less, by decreasing the number of quantum well layers 32a including InGaN to be less than 5, that is, the total thickness of the quantum well layers 32a including InGaN to be less than 15 nm, the absorption conversion rate of the third light-emitting structure 30 may be within 3%.

The green light absorbed in the third light-emitting structure 30 may be converted into red light. In this state, red light by absorption-induced-luminescence may serve as one of the reasons for color mixing. Referring back to FIG. 5, the absorption coefficient of the third light-emitting structure 30 with respect to green light may be 1.0×10⁴ cm⁻¹. When the peak IQE of the third light-emitting structure 30 is constant as 10%, by changing the number of quantum well layers 32a including InGaN, the absorption conversion rate by green light changes along a line L23 that is parallel to the horizontal axis and has an absorption coefficient of 1.0×10⁴ cm⁻¹. The absorption conversion rate increases as the total number of quantum well layers 32a including InGaN increases, and decrease as the number of quantum well layers 32a including InGaN decreases. For example, in FIG. 5, as indicated by R4, when the total number of quantum well layers 32a including InGaN is 10, that is, the total thickness of the quantum well layers 32a including InGaN is 30 nm, the absorption conversion rate by green light may be 0.30%. In FIG. 5, as indicated by R5, when the total number of quantum well layers 32a including InGaN is 5, that is, the total thickness of the quantum well layers 32a including InGaN is 15 nm, the absorption conversion rate by green light may be 0.15%. In FIG. 5, as indicated by R6, when the total number of quantum well layers 32a including InGaN is 3, that is, the total thickness of the quantum well layers 32a including InGaN is 9 nm, the absorption conversion rate by green light may be 0.09%. Accordingly, the sum of the absorption conversion rate of blue light and the absorption conversion rate by green light of the third light-emitting structure 30 may be within 3%.

In summary of the above, a combination of the total thickness and the total numbers of the quantum well layers 22a and 32a of the second light-emitting structure 20 and the third light-emitting structure 30 is available as follows according to the peak IQEs of the second light-emitting structure 20 and the third light-emitting structure 30. For example, the peak IQEs of the second light-emitting structure 20 and the third light-emitting structure 30 are 30% or less and 10% or less, respectively, the total thickness of each of the quantum well layers 22a and 32a of the second light-emitting structure 20 and the third light-emitting structure 30 may be 30 nm or less, and the total number of each of quantum well layers 22a and 32a of the second light-emitting structure 20 and the third light-emitting structure 30 may be 10 or less. When the peak IQEs of the second light-emitting structure 20 and the third light-emitting structure 30 are 30% or less and 20% or less, respectively, the total thicknesses of the quantum well layers 22a and 32a of the second light-emitting structure 20 and the third light-emitting structure 30 may be 30 nm or less and 15 nm or less, respectively, and the total numbers of the quantum well layers 22a and 32a of the second light-emitting structure 20 and the third light-emitting structure 30 may be 10 or less and 5 or less, respectively. When the peak IQEs of the second light-emitting structure 20 and the third light-emitting structure 30 are 60% or less and 10% or less, respectively, the total thicknesses of the quantum well layers 22a and 32a of the second light-emitting structure 20 and the third light-emitting structure 30 may be 15 nm or less and 30 nm or less, respectively, and the total numbers of the quantum well layers 22a and 32a of the second light-emitting structure 20 and the third light-emitting structure 30 may be 5 or less and 10 or less, respectively. When the peak IQEs of the second light-emitting structure 20 and the third light-emitting structure 30 are 60% or less and 20% or less, respectively, the total thickness of each of the quantum well layers 22a and 32a of the second light-emitting structure 20 and the third light-emitting structure 30 may be 15 nm or less, and the total number of each of quantum well layers 22a and 32a of the second light-emitting structure 20 and the third light-emitting structure 30 may be 5 or less.

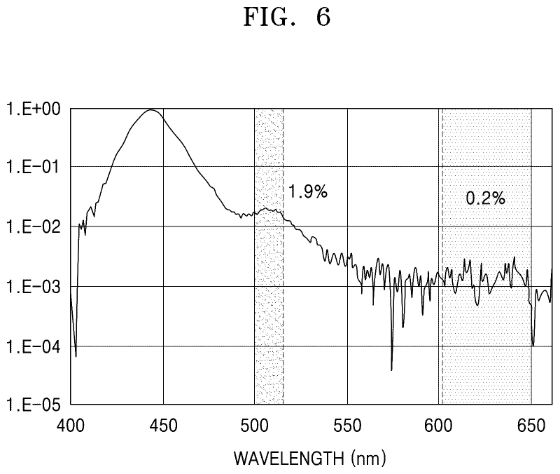

FIG. 6 is a graph showing an absorption spectrum of light emitted from the light-emitting element 1 illustrated in FIG. 1, when the light-emitting element generates blue light. The first conductive semiconductor layers 11, 21, and 31, and the second conductive semiconductor layers 13, 23, and 33 may include n-GaN and p-GaN, respectively. The active layers 12, 22, and 33 may each have an AlGaN/GaN multi-quantum well structure. The total number of layers and the total thickness of each of the quantum well layers 12a, 22a, and 23a may be 10 nm and 30 nm, respectively. The peak IQEs of the first light-emitting structure 10, the second light-emitting structure 20, and the third light-emitting structure 30 may be 50%, 30%, and 20%, respectively. Referring to FIG. 6, the absorption conversion rates of the second light-emitting structure 20 and the third light-emitting structure 30 of blue light may be 1.9% and 0.2%, respectively, and thus, it may be seen that the values are quite less than 5.31% and 2.01% that are expected values by the simulation.

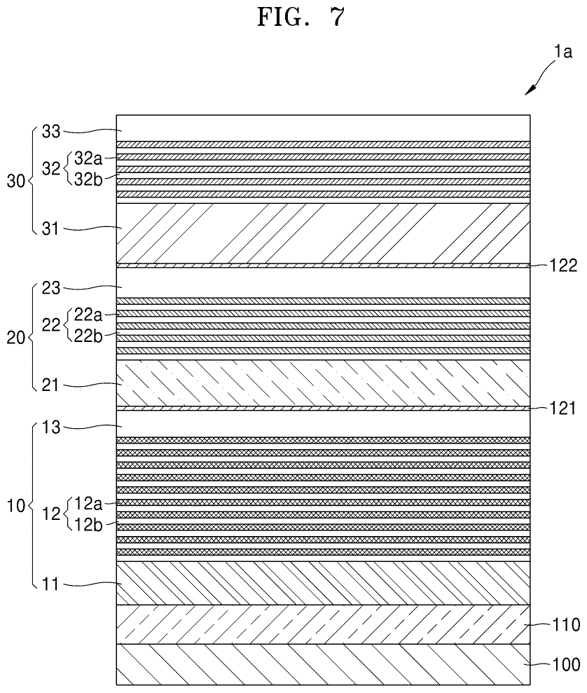

FIG. 7 is a schematic cross-sectional view of the light-emitting element 1a according to an embodiment. The light-emitting element 1a of the present embodiment is a vertical stack-type light-emitting element in which a plurality of sub-pixels are vertically stacked. The light-emitting element 1a may be, for example, a monolithic color micro-LED. The light-emitting element 1a of the present embodiment differs from the light-emitting element 1 illustrated in FIG. 1 in that the former includes insulating layers 121 and 122. In the following descriptions, like elements are indicated by like reference numerals, and differences are mainly described while redundant descriptions are omitted.

Referring to FIG. 7, the insulating layer 121 may be provided between the first light-emitting structure 10 and the second light-emitting structure 20. The insulating layer 121 may electrically insulate the second conductive semiconductor layer 13 of the first light-emitting structure 10 from the first conductive semiconductor layer 21 of the second light-emitting structure 20. The insulating layer 122 may be provided between the second light-emitting structure 20 and the third light-emitting structure 30. The insulating layer 122 may electrically insulate the second conductive semiconductor layer 23 of the second light-emitting structure 20 from the first conductive semiconductor layer 31 of the third light-emitting structure 30. The insulating layers 121 and 122 may include, for example, AlGaN.

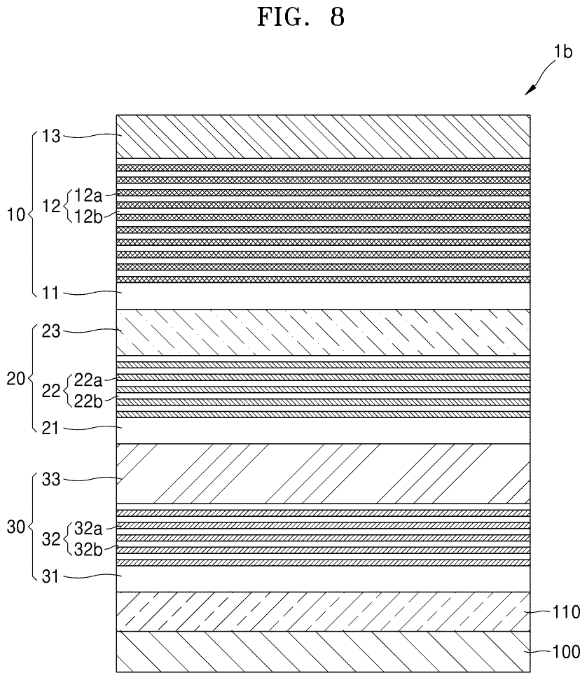

FIG. 8 is a schematic cross-sectional view of a light-emitting element 1b according to an embodiment. The light-emitting element 1b of the present embodiment is a vertical stack-type light-emitting element in which a plurality of sub-pixels are vertically stacked. The light-emitting element 1b may be, for example, a monolithic color micro-LED. The light-emitting element 1b of the present embodiment differs from the light-emitting element 1 illustrated in FIG. 1 in that, in the former, the third light-emitting structure 30, the second light-emitting structure 20, and the first light-emitting structure 10 are sequentially stacked on and above the substrate 100 or the buffer layer 110. In other words, the first light-emitting structure 10 may be located at the top layer (e.g., may be the uppermost light-emitting structure) with respect to a light emission direction. The descriptions on the first light-emitting structure 10, the second light-emitting structure 20, and the third light-emitting structure 30 of FIG. 1 may be identically applied to the first light-emitting structure 10, the second light-emitting structure 20, and the third light-emitting structure 30 of FIG. 8.

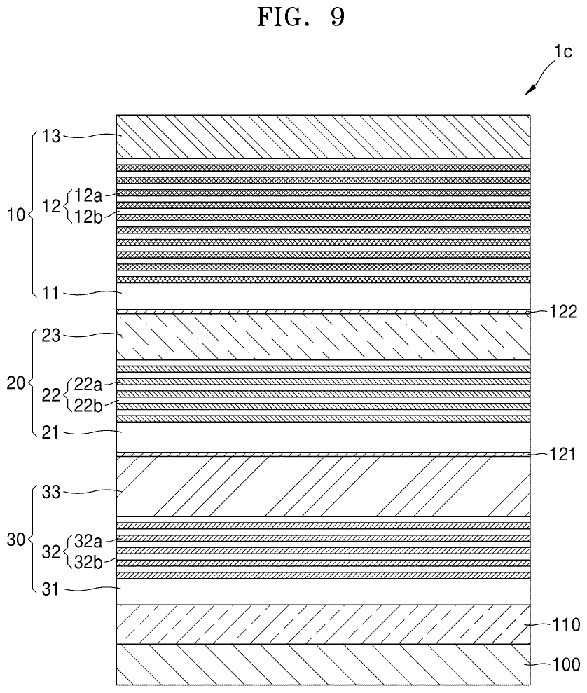

FIG. 9 is a schematic cross-sectional view of a light-emitting element 1c according to an embodiment. The light-emitting element 1c of the present embodiment is a vertical stack-type light-emitting element in which a plurality of sub-pixels are vertically stacked. The light-emitting element 1c may be, for example, a monolithic color micro-LED. The light-emitting element 1c of the present embodiment differs from the light-emitting element 1b of FIG. 8 in that the former includes the insulating layers 121 and 122. Accordingly, like elements are indicated by like reference numerals, and redundant descriptions may be omitted.

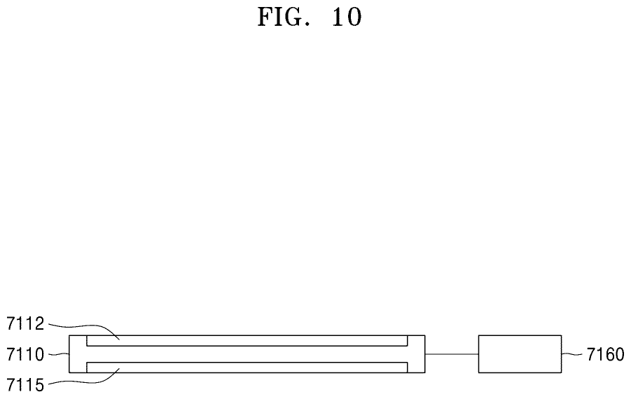

FIG. 10 is a schematic view showing an example of a display device. Referring to FIG. 10, the display device may include a display panel 7110 and a controller 7160. The display panel 7110 may include a light-emitting structure 7112 and a driving circuit 7115 that switches the light-emitting structure 7112 on or off. The light-emitting structure 7112 may include a plurality of light-emitting elements described above with reference to FIGS. 1 to 9. The light-emitting elements may be arranged in, for example, a two-dimensional array. The driving circuit 7115 may include a plurality of switching elements that individually switch the light-emitting elements on or off. The controller 7160 may input a signal for switching the light-emitting elements on or off to the driving circuit 7115 in response to an image signal.

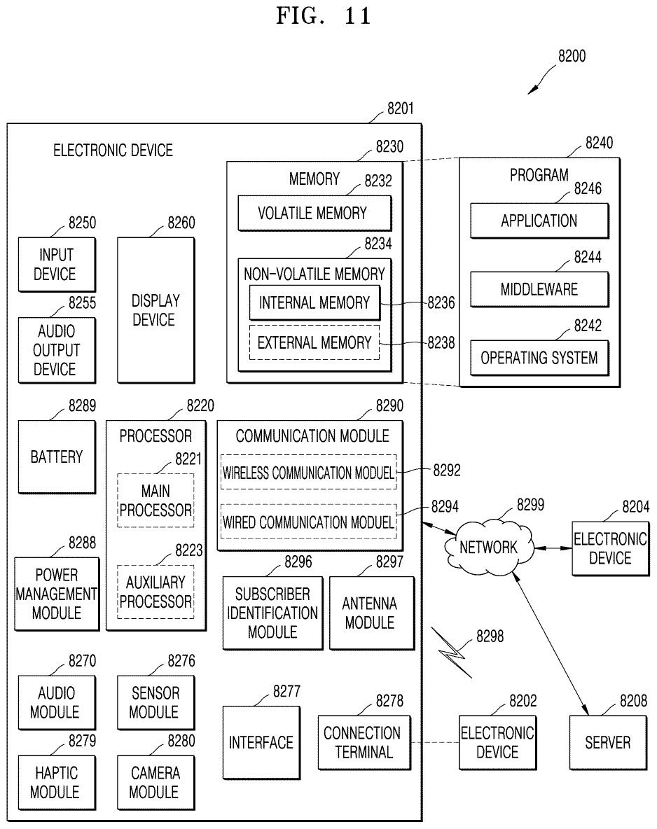

FIG. 11 is a block diagram showing an example of an electronic device 8201 including a display. Referring to FIG. 11, the electronic device 8201 may be provided in a network environment 8200. In the network environment 8200, the electronic device 8201 may communicate with another electronic device 8202 through a first network 8298 (e.g., a short-range wireless communication network, etc.), or another electronic device 8204 and/or a server 8208 through a second network 8299 (e.g., a long-range wireless communication network, etc.). The electronic device 8201 may communicate with the electronic device 8204 through the server 8208. The electronic device 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of the constituent elements may be omitted or another constituent element may be added. Some of these constituent elements may be implemented as one integrated circuit. For example, the sensor module 8276 (e.g., a fingerprint sensor, an iris sensor, an illuminance sensor, etc.) may be implemented by being embedded in the display device 8260 (e.g., a display, etc.).

The processor 8220 may control, by executing software (e.g., a program 8240, etc.), one or a plurality of other constituent elements (e.g., a hardware or software constituent element, etc.) of the electronic device 8201, and perform a variety of data processing or operations. As part of data processing or operations, the processor 8220 may load commands and/or data received from other constituent elements (e.g., the sensor module 8276, the communication module 8290, etc.) in a volatile memory 8232, process the command and/or data stored in the volatile memory 8232, and store resultant data in a non-volatile memory 8234. The processor 8220 may include a main processor 8221 (e.g., a central processing unit, an application processor, etc.) and an auxiliary processor 8223 (e.g., a graphics processing unit, an image signal processor, a sensor hub processor, a communication processor, etc.), which are operable independently or together. The auxiliary processor 8223 may consume less power than the main processor 8221 and may perform a specialized function.

The auxiliary processor 8223 may control functions and/or states related to some constituent elements (e.g., the display device 8260, the sensor module 8276, the communication module 8290, etc.) of the electronic device 8201, instead of the main processor 8221 when the main processor 8221 is in an inactive state (e.g., a sleep state), or with the main processor 8221 when the main processor 8221 is in an active state (e.g., an application execution state). The auxiliary processor 8223 (e.g., an image signal processor, a communication processor, etc.) may be implemented as a part of functionally related other constituent elements (e.g., the camera module 8280, the communication module 8290, etc.).

The memory 8230 may store various pieces of data needed for constituent elements (e.g., the processor 8220, the sensor module 8276, etc.) of the electronic device 8201. The data may include, for example, software (e.g., the program 8240, etc.) and input data and/or output data regarding commands related thereto. The memory 8230 may include the volatile memory 8232 and/or the non-volatile memory 8234. The non-volatile memory 8234 may include an internal memory 8236 and may further include an external memory 8238.

The program 8240 may be stored as software in the memory 8230, and may include an operating system 8242, middleware 8244, and/or an application 8246.

The input device 8250 may receive commands and/or data to be used in the constituent elements (e.g., the processor 8220, etc.) of the electronic device 8201, from the outside (e.g., a user, etc.) of the electronic device 8201. The input device 8250 may include a microphone, a mouse, a keyboard, and/or a digital pen (e.g., a stylus pen, etc.).

The audio output device 8255 may output an audio signal to the outside of the electronic device 8201. The audio output device 8255 may include a speaker and/or a receiver. The speaker may be used for general purposes such as multimedia playback or recording playback, and the receiver may be used to receive incoming calls. The receiver may be combined as a part of the speaker or implemented as an independent separate device.

The display device 8260 may visually provide information to the outside of the electronic device 8201. The display device 8260 may include a display, a hologram device, or a projector, and a control circuit for controlling such a device. The display device 8260 may include the display described with reference to FIG. 10. The display device 8260 may include touch circuitry set to sense a touch, and/or a sensor circuit (e.g., a pressure sensor, etc.) set to measure the strength of a force generated by the touch.

The audio module 8270 may convert sound into an electrical signal or reversely an electrical signal into sound. The audio module 8270 may obtain sound through the input device 8250, or output sound through the audio output device 8255 and/or a speaker and/or headphones of another electronic device (e.g., the electronic device 8202, etc.) connected to the electronic device 8201 in a wired or wireless manner.

The sensor module 8276 may sense an operation state (e.g., power, a temperature, etc.) of the electronic device 8201, or an external environment state (e.g., a user state, etc.), and generate an electrical signal and/or data value corresponding to a sensed state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols to be used for connecting the electronic device 8201 to another electronic device (e.g., the electronic device 8202, etc.) in a wired or wireless manner. The interface 8277 may include a high definition multimedia interface (HDMI), a universal serial bus (USB) interface, a security digital (SD) card interface, and/or an audio interface.

A connection terminal 8278 may include a connector for physically connecting the electronic device 8201 to another electronic device (e.g., the electronic device 8202, etc.). The connection terminal 8278 may include a HDMI connector, a USB connector, an SD card connector, and/or an audio connector (e.g., a headphone connector, etc.).

The haptic module 8279 may convert electrical signals into mechanical stimuli (e.g., vibrations, movements, etc.) or electrical stimuli that are perceivable by a user through tactile or motor sensations. The haptic module 8279 may include a motor, a piezoelectric device, and/or an electrical stimulation device.

The camera module 8280 may capture a still image and a video. The camera module 8280 may include a lens assembly including one or a plurality of lenses, image sensors, image signal processors, and/or flashes. The lens assembly included in the camera module 8280 may collect light emitted from an object that is a target for image capturing.

The power management module 8288 may manage power supplied to the electronic device 8201. The power management module 8288 may be implemented as a part of a power management integrated circuit (PMIC).

The battery 8289 may supply power to the constituent elements of the electronic device 8201. The battery 8289 may include non-rechargeable primary cells, rechargeable secondary cells, and/or fuel cells.

The communication module 8290 may establish a wired communication channel and/or a wireless communication channel between the electronic device 8201 and another electronic device (e.g., the electronic device 8202, the electronic device 8204, the server 8208, etc.), and support communication through an established communication channel. The communication module 8290 may be operated independently of the processor 8220 (e.g., the application processor, etc.), and may include one or a plurality of communication processors supporting wired communication and/or wireless communication. The communication module 8290 may include a wireless communication module 8292 (e.g., a cellular communication module, a short-range wireless communication module, a global navigation satellite system (GNSS) communication module, etc.), and/or a wired communication module 8294 (e.g., a local area network (LAN) communication module, a power line communication module, etc.). Among the above communication modules, a corresponding communication module may communicate with another electronic device through the first network 8298 (e.g., a short-range communication network such as Bluetooth, WiFi Direct, or infrared data association (IrDA)) or the second network 8299 (e.g., a long-range communication network such as a cellular network, the Internet, or a computer network (e.g., a local area network (LAN), a wide area network (WAN), etc.)). These various types of communication modules may be integrated into one constituent element (e.g., a single chip, etc.), or may be implemented as a plurality of separate constituent elements (e.g., multiple chips). The wireless communication module 8292 may verify and authenticate the electronic device 8201 in a communication network such as the first network 8298 and/or the second network 8299 by using subscriber information (e.g., an international mobile subscriber identifier (IMSI), etc.) stored in the subscriber identification module 8296.

The antenna module 8297 may transmit signals and/or power to the outside (e.g., another electronic device, etc.) or receive signals and/or power from the outside. An antenna may include an emitter formed in a conductive pattern on a substrate (e.g., a printed circuit board (PCB), etc.). The antenna module 8297 may include one or a plurality of antennas. When the antenna module 8297 includes a plurality of antennas, the communication module 8290 may select, from among the antennas, an appropriate antenna for a communication method used in a communication network such as the first network 8298 and/or the second network 8299. Signals and/or power may be transmitted or received between the communication module 8290 and another electronic device through the selected antenna. Other parts (e.g., a radio-frequency integrated circuit (RFIC), etc.) than the antenna may be included as a part of the antenna module 8297.

Some of the constituent elements may be connected to each other through a communication method between peripheral devices (e.g., a bus, general purpose input and output (GPIO), a serial peripheral interface (SPI), a mobile industry processor interface (MIPI), etc.) and may mutually exchange signals (e.g., commands, data, etc.).

The command or data may be transmitted or received between the electronic device 8201 and the electronic device 8204 in the outside through the server 8208 connected to the second network 8299. The electronic devices 8202 and 8204 may be of a type that is the same as or different from the electronic device 8201. All or a part of operations executed in the electronic device 8201 may be executed in one or a plurality of the electronic devices (e.g., the electronic device 8202, the electronic device 8204, and the server 8208). For example, when the electronic device 8201 needs to perform a function or service, the electronic device 8201 may request one or a plurality of other electronic devices to perform part or the whole of the function or service, instead of performing the function or service by itself. The one or a plurality of the electronic devices receiving the request may perform additional functions or services related to the request and transmit a result of the performance to the electronic device 8201. To this end, cloud computing, distributed computing, and/or client-server computing technology may be used.

The electronic device 8201 described above may be applied to various devices. Various components of the electronic device 8201 described above may be appropriately modified according to the functions of devices, and appropriate components for performing the functions of the devices may be added. In the following descriptions, application examples of the electronic device 8201 are described.

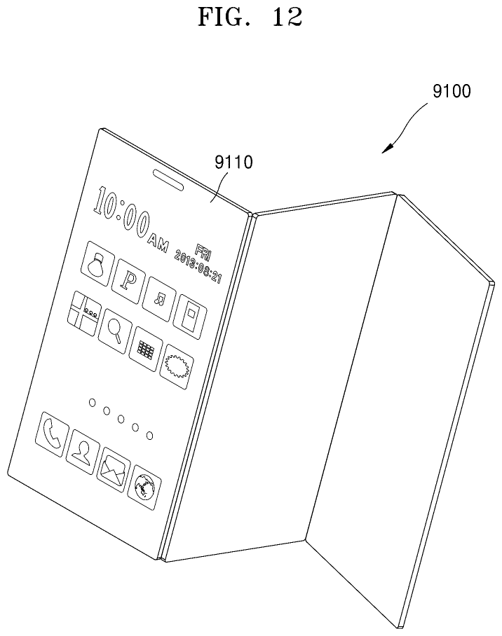

FIG. 12 illustrates an example of a mobile device 9100 as an application example of the electronic device of FIG. 11. The mobile device 9100 may include a display device 9110. The display device 9110 may include the display device described with reference to FIG. 10. The display device 9110 may have a foldable structure such as, for example, a multi-foldable structure.

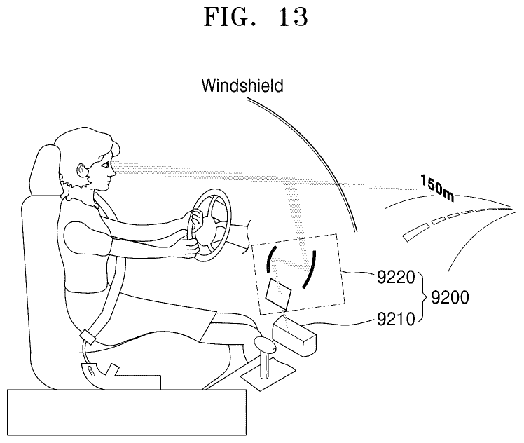

FIG. 13 illustrates an example of a head-up display device 9200 for vehicles as an application example of the electronic device of FIG. 11. The head-up display device 9200 for vehicles may include a display 9210 provided in one area of a vehicle, and an optical path change member 9220 for converting an optical path so that a driver can see an image generated from the display 9210. The display 9210 may include the display device described with reference to FIG. 10.

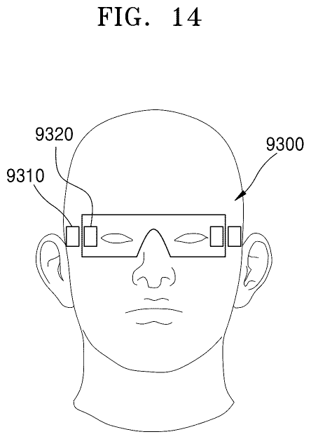

FIG. 14 illustrates an example of augmented reality glasses (or virtual reality glasses) 9300 as an application example of the electronic device of FIG. 11. The augmented reality glasses (or virtual reality glasses) 9300 may include a projection system 9310 for forming an image, and a component 9320 that guides an image from the projection system 9310 to proceed toward a user′s eye. The projection system 9310 may include the display device described with reference to FIG. 10.

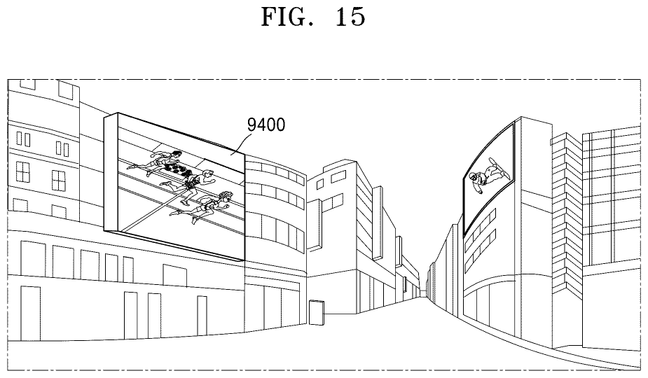

FIG. 15 illustrates an example of a large signage (e.g., a signage 9400) as an application example of the electronic device of FIG. 11. The signage 9400 may include the display device described with reference to FIG. 10. The signage 9400 may be used for outdoor advertising using a digital information display and may control advertising content or the like through a communication network. The signage 9400 may be implemented through, for example, the electronic device described with reference to FIG. 11.

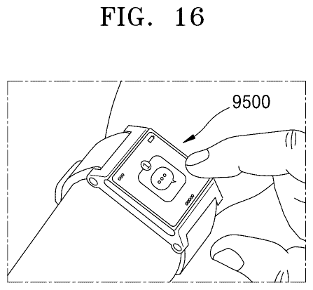

FIG. 16 illustrates an example of a wearable display 9500 as an application example of the electronic device of FIG. 11. The wearable display 9500 may include the display device described with reference to FIG. 10. The wearable display 9500 may be implemented through the electronic device described with reference to FIG. 11.

A light-emitting element according to an embodiment or a display including the light-emitting element may be applied to various products such as, for example, a rollable TV, a stretchable display, etc.

According to the embodiments, a light-emitting element, in which color mixing may be reduced by reducing the emission of red light and green light due to the absorption of blue light, and a display device employing the light-emitting element, may be implemented.

It should be understood that the example embodiments of the light-emitting element and the display including the same described herein should be considered in a descriptive sense only and not for purposes of limitation. Descriptions of features or aspects within each embodiment of the present disclosure should typically be considered as available for other similar features or aspects in other embodiments of the present disclosure. While one or more embodiments have been described with reference to the figures, it will be understood by those of ordinary skill in the art that various changes in form and details may be made therein without departing from the spirit and scope of the present disclosure.

What is claimed is:

1. A light-emitting element comprising:
a substrate;
a first light-emitting structure configured to emit blue light;
a second light-emitting structure configured to emit green light; and
a third light-emitting structure configured to emit red light,
wherein the first light-emitting structure, the second light-emitting structure, and the third light-emitting structure are stacked on the substrate,
wherein each of the first light-emitting structure, the second light-emitting structure, and the third light-emitting structure comprises:
a first conductive semiconductor layer,
an active layer comprising a multi-quantum well structure, wherein the multi-quantum well structure comprises quantum well layers and barrier layers that are alternately stacked, and
a second conductive semiconductor layer,
wherein the first conductive semiconductor layer, the active layer, and the second conductive semiconductor layer are sequentially stacked, and
wherein an absorption conversion rate of the third light-emitting structure of the blue light is 3% or less.

2. The light-emitting element of claim 1, wherein an absorption conversion rate of the second light-emitting structure of the blue light is 6% or less.

3. The light-emitting element of claim 1, wherein a total thickness and a total number of the quantum well layers of the third light-emitting structure are respectively less than or equal to a total thickness and a total number of the quantum well layers of the first light-emitting structure.

4. The light-emitting element of claim 1, wherein a total thickness and a total number of the quantum well layers of the second light-emitting structure are respectively less than or equal to a total thickness and a total number of the quantum well layers of the first light-emitting structure.

5. The light-emitting element of claim 1, wherein the quantum well layers comprise InGaN,
the barrier layers comprise GaN,
the first conductive semiconductor layer comprises n-GaN, and
the second conductive semiconductor layer comprises p-GaN.

6. The light-emitting element of claim 5, wherein an indium concentration of the quantum well layers of the first light-emitting structure is 13% to 18%,
an indium concentration of the quantum well layers of the second light-emitting structure is 20% to 25%, and
an indium concentration of the quantum well layers of the third light-emitting structure is 30% to 35%.

7. The light-emitting element of claim 5, wherein a total thickness of the quantum well layers of each of the first light-emitting structure, the second light-emitting structure, and the third light-emitting structure is 30 nm or less.

8. The light-emitting element of claim 7, wherein a total number of the quantum well layers of each of the first light-emitting structure, the second light-emitting structure, and the third light-emitting structure is 10 or less.

9. The light-emitting element of claim 5, wherein a peak internal quantum efficiency of the first light-emitting structure is 50% or less,
a total thickness of the quantum well layers of the first light-emitting structure is 30 nm or less, and
a total number of the quantum well layers of the first light-emitting structure is 10 or less.

10. The light-emitting element of claim 9, wherein a peak internal quantum efficiency of the second light-emitting structure is 30% or less,
a peak internal quantum efficiency of the third light-emitting structure is 10% or less,
a total thickness of the quantum well layers of each of the second light-emitting structure and the third light-emitting structure is 30 nm or less, and
a total number of the quantum well layers of each of the second light-emitting structure and the third light-emitting structure is 10 or less.

11. The light-emitting element of claim 9, wherein a peak internal quantum efficiency of the second light-emitting structure is 30% or less,
a peak internal quantum efficiency of the third light-emitting structure is 20% or less,
a total thicknesses of the quantum well layers of the second light-emitting structure is 30 nm or less,
a total thicknesses of the quantum well layers of the third light-emitting structure is 15 nm or less,
a total number of the quantum well layers of the second light-emitting structure is 10 or less, and
a total number of the quantum well layers of the third light-emitting structure is 5 or less.

12. The light-emitting element of claim 9, wherein a peak internal quantum efficiency of the second light-emitting structure is 60% or less,
a peak internal quantum efficiency of the third light-emitting structure is 10% or less,
a total thicknesses of the quantum well layers of the second light-emitting structure is 15 nm or less,
a total thicknesses of the quantum well layers of the third light-emitting structure is 30 nm or less,
a total number of the quantum well layers of the second light-emitting structure is 5 or less, and
a total number of the quantum well layers of the third light-emitting structure is 10 or less.

13. The light-emitting element of claim 5, wherein a peak internal quantum efficiency of the second light-emitting structure is 60% or less,
a peak internal quantum efficiency of the third light-emitting structure is 20% or less,
a total thickness of the quantum well layers of each of the second light-emitting structure and the third light-emitting structure is 15 nm or less, and
a total number of the quantum well layers of each of the second light-emitting structure and the third light-emitting structure is 5 or less.

14. The light-emitting element of claim 1, further comprising:
a first insulating layer between the first light-emitting structure and the second light-emitting structure; and
a second insulating layer between the second light-emitting structure and the third light-emitting structure.

15. The light-emitting element of claim 14, wherein the first insulating layer and the second insulating layer comprise AlGaN.

16. The light-emitting element of claim 1, wherein the third light-emitting structure is a top light-emitting structure, among the first light-emitting structure, the second light-emitting structure, and the third light-emitting structure, with respect to a light emission direction of the light-emitting element.

17. The light-emitting element of claim 1, wherein the first light-emitting structure is an uppermost light-emitting structure, among the first light-emitting structure, the second light-emitting structure, and the third light-emitting structure, with respect to a light emission direction of the light-emitting element.

18. A display device comprising:
a display panel comprising:
a plurality of light-emitting elements, each of the plurality of light-emitting elements comprising:
a first light-emitting structure configured to emit blue light;
a second light-emitting structure configured to emit green light; and
a third light-emitting structure configured to emit red light; and
a driving circuit configured to switch the plurality of light-emitting elements on or off;
a controller configured to input, based on an image signal, a signal for switching the plurality of light-emitting elements on or off to the driving circuit,
wherein the first light-emitting structure, the second light-emitting structure, and the third light-emitting structure are alternatively stacked on the substrate,
wherein each of the first light-emitting structure, the second light-emitting structure, and the third light-emitting structure comprises:
a first conductive semiconductor layer;
an active layer comprising a multi-quantum well structure, wherein the multi-quantum well structure comprises quantum well layers and barrier layers that are alternately; and
a second conductive semiconductor layer,
wherein the first conductive semiconductor layer, the active layer, and the second conductive semiconductor layer are sequentially stacked, and
wherein an absorption conversion rate of the first light-emitting structure of the blue light is 3% or less.

19. A light-emitting element comprising:
a first light-emitting structure configured to emit first light of a first color;
a second light-emitting structure configured to emit second light of a second color; and
a third light-emitting structure configured to emit third light of a third color,
wherein the first color, the second color, and the third color are different from each other,
wherein the first light-emitting structure, the second light-emitting structure, and the third light-emitting structure are stacked on the substrate,
wherein each of the first light-emitting structure, the second light-emitting structure, and the third light-emitting structure comprises:
a first conductive semiconductor layer,
an active layer comprising a multi-quantum well structure, wherein the multi-quantum well structure comprises quantum well layers and barrier layers that are alternately stacked, and
a second conductive semiconductor layer,
wherein the first conductive semiconductor layer, the active layer, and the second conductive semiconductor layer are sequentially stacked, and
wherein an absorption conversion rate of the third light-emitting structure of the first light is 3% or less.

20. The light-emitting element of claim 19, wherein an absorption conversion rate of the second light-emitting structure of the first light is 6% or less.
